(19) United States
(12) Patent Application Publication
(10) Pub. No.: US 2024/0145354 A1
(43) Pub. Date: May 2, 2024

(54) SEMICONDUCTOR DEVICE AND A METHOD FOR MANUFACTURING SUCH SEMICONDUCTOR DEVICE

(71) Applicant: NEXPERIA B.V., Nijmegen (NL)

(72) Inventors: Arnel Taduran, Cabuyao (PH); Ricardo Yandoc, Manchester (GB); Homer Malveda, Cabuyao (PH); Antonio Dimaano, Cabuyao (PH)

(73) Assignee: NEXPERIA B.V., Nijmegen (NL)

(21) Appl. No.: 18/494,946

(22) Filed: Oct. 26, 2023

(30) Foreign Application Priority Data
Oct. 26, 2022 (EP) 22203855.6

(51) Int. Cl. H01L 23/495; H01L 21/48; H01L 21/56; H01L 23/31

(52) U.S. Cl. CPC H01L 23/49568; H01L 21/4825; H01L 21/4842; H01L 21/565; H01L 23/3107; H01L 23/49524; H01L 23/49575

(57) ABSTRACT

A semiconductor device and method of manufacturing is provided, including a lead frame with a first and a second lead frame surface, a semiconductor die including a first and a second semiconductor die surface, a clip including a flat and a corrugated part, the corrugated part includes at least one peak and one valley, and a mold compound, the second lead frame surface is connected to the first die surface of the die, and the second die surface of the die is connected to the corrugated part, and the mold compound encapsulates the semiconductor die, and the valley of the corrugated part, so that the mold compound forms an outer surface of the device with the peak of the corrugated part, at least part of the flat part of the clip, and the first lead frame surface of the lead frame is exposed.

### CROSS-REFERENCE TO RELATED APPLICATIONS

This application claims the benefit under 35 U.S.C. § 119(a) of European Application No. 22203855.6 filed Oct. 26, 2022, the contents of which are incorporated by reference herein in their entirety.

### BACKGROUND

### 1. Field of the Disclosure

The present disclosure relates to heat dissipation control in power packages. Accordingly, a novel method for manufacturing a semiconductor device is provided, as well as such novel semiconductor device having an improved heat dissipation.

### 2. Description of the Related Art

Power package poses concern on heat dissipation, and the majority of MOSFET devices are using either drain or source terminals as exposed heatsink elements attached on a printed circuit board, PCB. Continuous operation of this package will lead to over fatigue on either package or PCB. Mitigating this concern however are already available and various methods has been introduced through dual side cooling (top and bottom part of the package), preventing too much heat absorbed on the PCB through ambient heat dissipation.

US 2017/047274A1 discloses a system, a method, and a silicon chip package for providing structural strength, heat dissipation and electrical connectivity using a “W” shaped frame bonded to the one or more dies, wherein the “W” shaped frame provides compression strength to the silicon chip package when the one or more dies are bonded, and electrically conductivity between for the one or more dies to leads of silicon chip package, and heat dissipation for the silicon chip package.

Accordingly, it is a goal of the present disclosure to provide a novel power package with an improved heat dissipation.

### SUMMARY

According to a first example of the disclosure, a semiconductor device is proposed as outlined below. It comprises a lead frame comprising a first lead frame surface and a second lead frame surface, opposite the first lead frame surface, as well as a semiconductor die comprising a first semiconductor die surface and a second semiconductor die surface, opposite the first semiconductor die surface as well as a clip comprising a flat part and a corrugated part, wherein the corrugated part comprises at least two peaks and at least one valley.

In particular, the second lead frame surface of the lead frame is connected to the first semiconductor die surface of the semiconductor die, and the second semiconductor die surface of the semiconductor die is connected to the corrugated part of the clip, and a mold compound is used to encapsulate the semiconductor die, and the at least one valley of the corrugated part of the clip, such that the mold compound forms an outer surface of the semiconductor device with at least two peaks of the corrugated part of the clip, at least part of the flat part of the clip, and the first lead frame surface of the lead frame being exposed.

The exposed corrugated part and flat part of the clip effectively function as an enlarged heat dissipation surface, in particular at an upper or top face of the semiconductor device. Usually, heat generated during operating the semiconductor device is dissipated from an area with a high (hot) temperature towards an area with a lower (colder) temperature. Thus, the presence of additional heat sink functionality formed by the exposed corrugated part and flat part of the clip provides an additional heat dissipation at the upper surface of the semiconductor device aside from the commonly used heat sink formed by the drain terminal tab. Accordingly, this configuration results in an improved electrical efficiency of the semiconductor device, e.g. formed as a MOSFET or transistor.

In a preferred example, the second lead frame surface of the lead frame is connected to the first semiconductor die surface of the semiconductor die, and/or the second semiconductor die surface of the semiconductor die is connected to the corrugated part of the clip by means of soldering, sintering, or ultrasonic bonding. Soldering is the recommended process according to the example, as this allows for applying a required uniform solder volume, which prevents solder voids and/or insufficient soldering material.

Preferably, the mold compound and the at least one peak of the corrugated part of the clip forms a single planar surface, thus constituting an optimal heat sink surface with improved heat dissipation.

In preferred examples according to the disclosure, the lead frame and/or the clip are made of a conductive metal sheet, for example copper or aluminum.

In particular, wherein the clip is made of a metal sheet, preferably with a width or thickness of 200 μm. Preferably, a width or thickness of the corrugated part is two times the width of the metal sheet. This will provide a clip profile close to the top of the package, and allow the mold compound to penetrate on the corrugated part to prevent voiding or delamination.

In order to enlarge the heat dissipating surface of the clip, the corrugated part of the clip comprises three or four peaks.

The disclosure also pertains to a method of manufacturing a semiconductor device according to the disclosure as defined in claim 7. The method may comprise the steps of:
i) forming a clip which comprises a flat part and a corrugated part, wherein the corrugated part comprises at least two peaks and at least one valley,
ii) connecting a semiconductor die, which comprises a first semiconductor die surface and a second semiconductor die surface opposite first semiconductor die surface, to a lead frame, which comprises a first lead frame surface and a second lead frame surface opposite the first lead frame surface, such that the second lead frame surface of the lead frame is connected to the first semiconductor die surface of the semiconductor die,
iii) connecting the clip to the semiconductor device such that the second semiconductor die surface of the semiconductor die is connected to the corrugated part of the clip,
iv) encapsulating with a mold compound, such that the at least two peaks of the corrugated part of the clip, at least part of the flat part of the clip, and the first lead frame surface of the lead frame are exposed.

These method steps result in a semiconductor device wherein the exposed corrugated part and flat part of the clip effectively function as an enlarged heat dissipation surface, in particular at an upper or top face of the semiconductor device.

In a preferred example of the method according to the disclosure, the connecting steps ii) and iii) further comprise the sub-step of:
v) applying a connection by means of soldering, sintering, or ultrasonic bonding between the second lead frame surface of the lead frame and the first semiconductor die surface of the semiconductor die and/or between the second semiconductor die surface of the semiconductor die and the corrugated part of the clip.

Preferably, a soldering connection is performed, as soldering is the recommended process according to the example, as this allows for applying a required uniform solder volume, which prevents solder voids and/or insufficient soldering material.

In a preferred example, the encapsulating step iv) is followed by the step of:
vi) polishing, such that the mold compound and the at least one peak of the corrugated part of the clip forms a single plane surface. This method step results in a semiconductor device with an effective, flat heat sink upper surface with an improved heat dissipation.

In examples of the method according to the disclosure, the clip is made by punching a metal sheet or by forming a metal sheet.

In a final step, the semiconductor device is singulated from the lead frame.

### BRIEF DESCRIPTION OF DRAWINGS

The disclosure will now be discussed with reference to the drawings, which show in:

FIGS. 1a, 1b, 1c and 1d depict in a schematic way the sequence steps of manufacturing an example of a semiconductor device according to the disclosure.

FIGS. 2a, 2b, 2c, 2d, 2e, 2f and 2g depict in another schematic way the sequence steps of a method of manufacturing a semiconductor device according to the disclosure.

FIG. 3 depicts an example of a semiconductor device according to the disclosure.

FIGS. 4a, 4b, 4c and 4d depict in a schematic way the sequence steps of manufacturing an example of an corrugated clip for use in a semiconductor device according to the disclosure.

### DETAILED DESCRIPTION

For a proper understanding of the disclosure, in the detailed description below corresponding elements or parts of the disclosure will be denoted with identical reference numerals in the drawings.

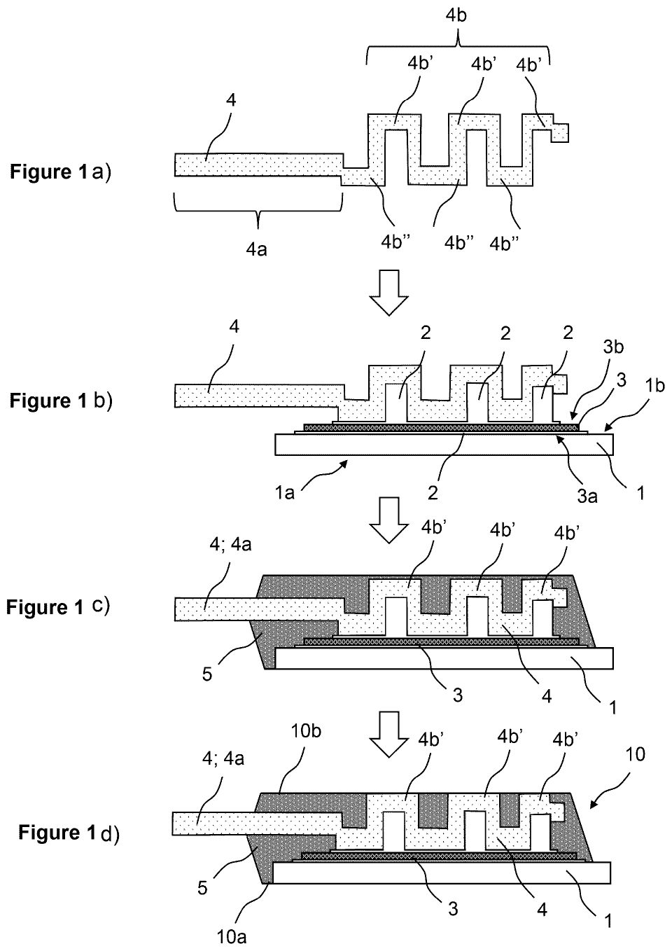

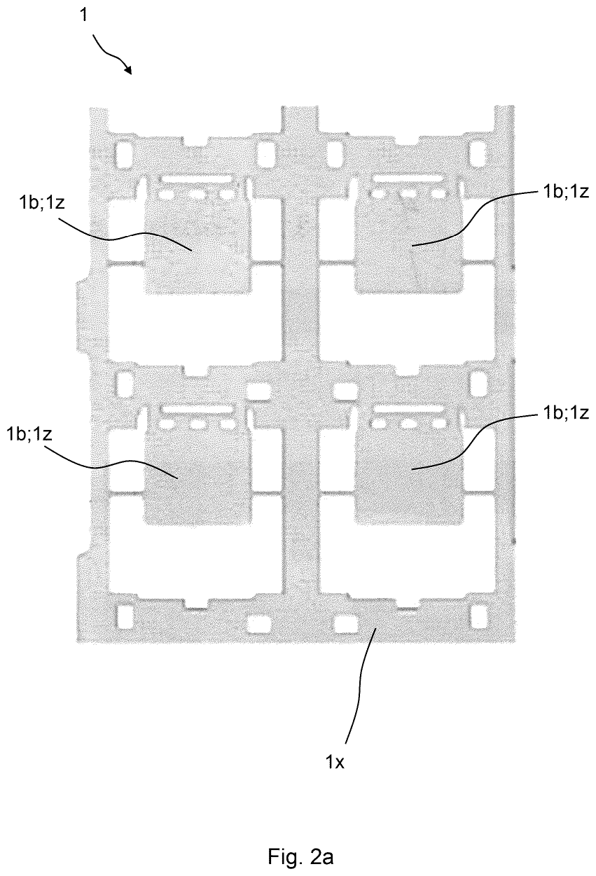

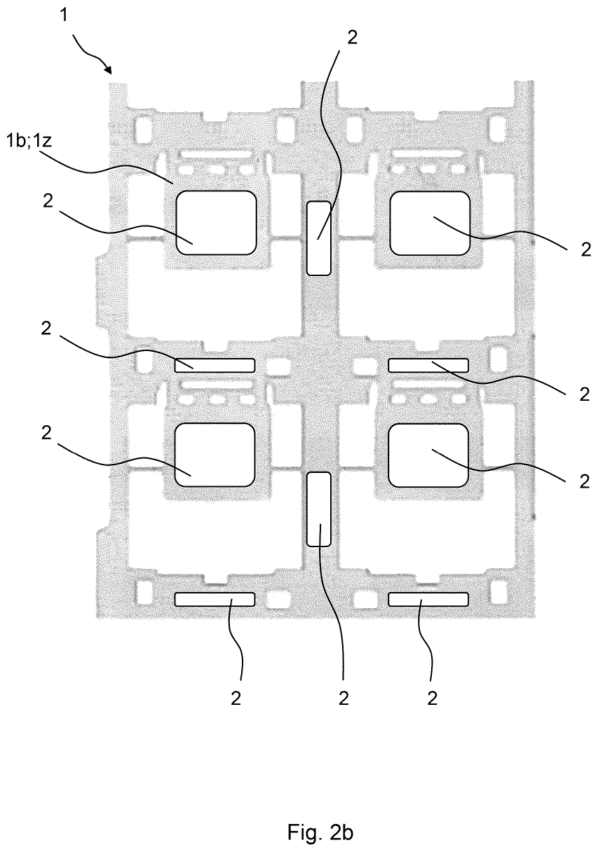

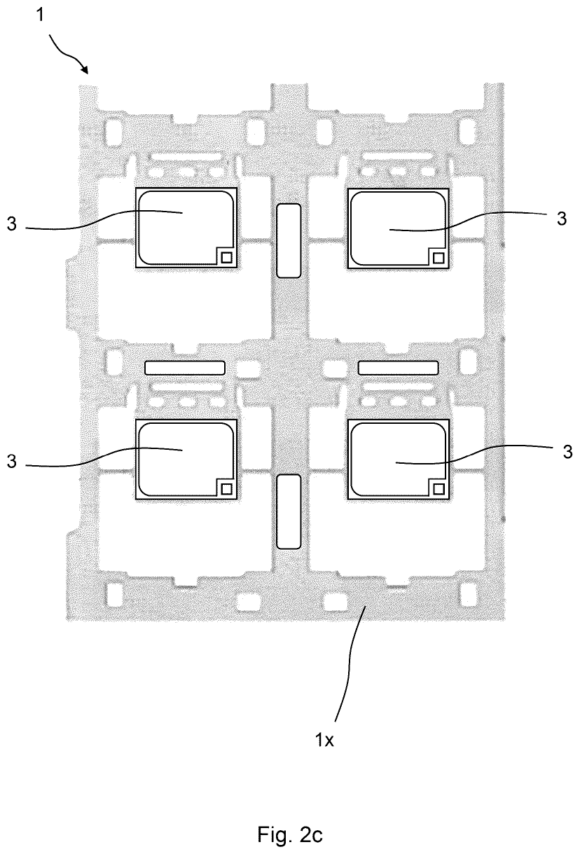

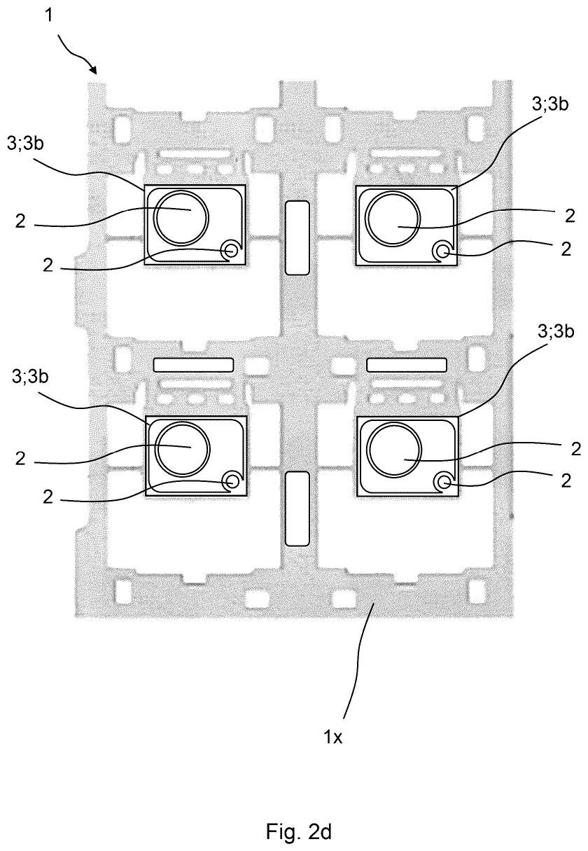

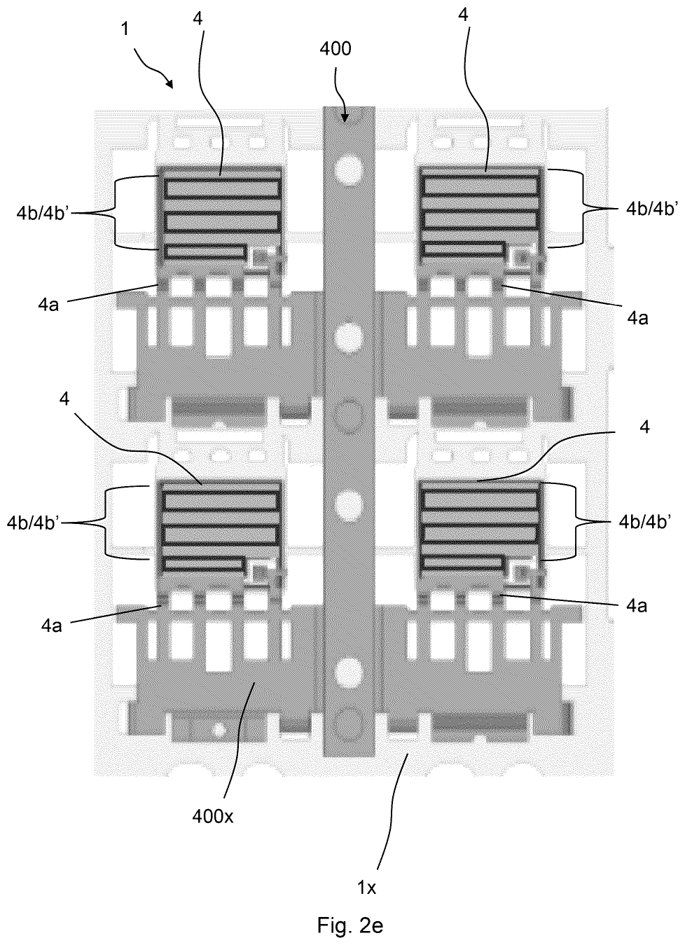

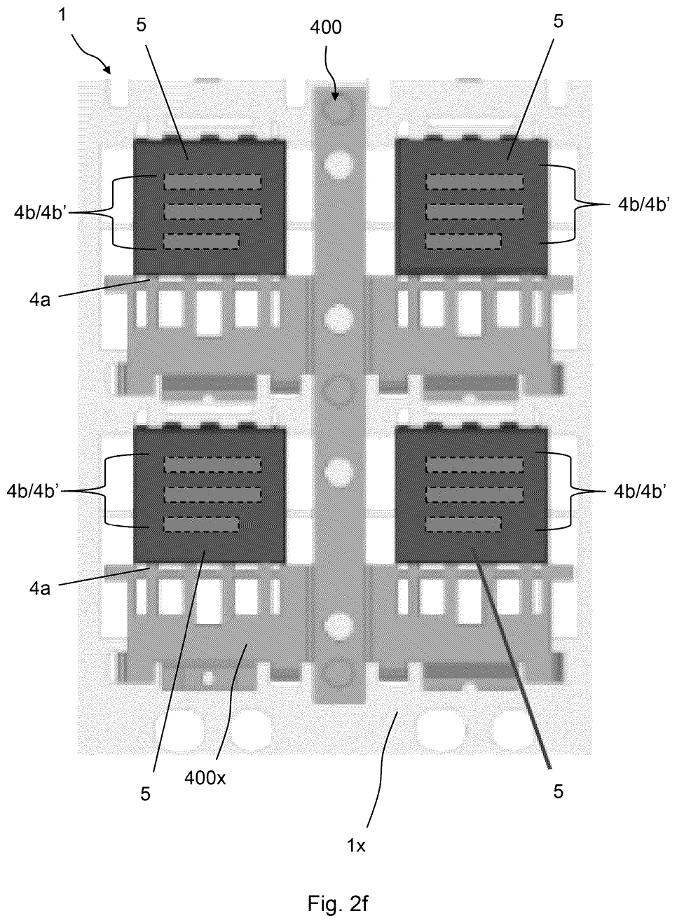

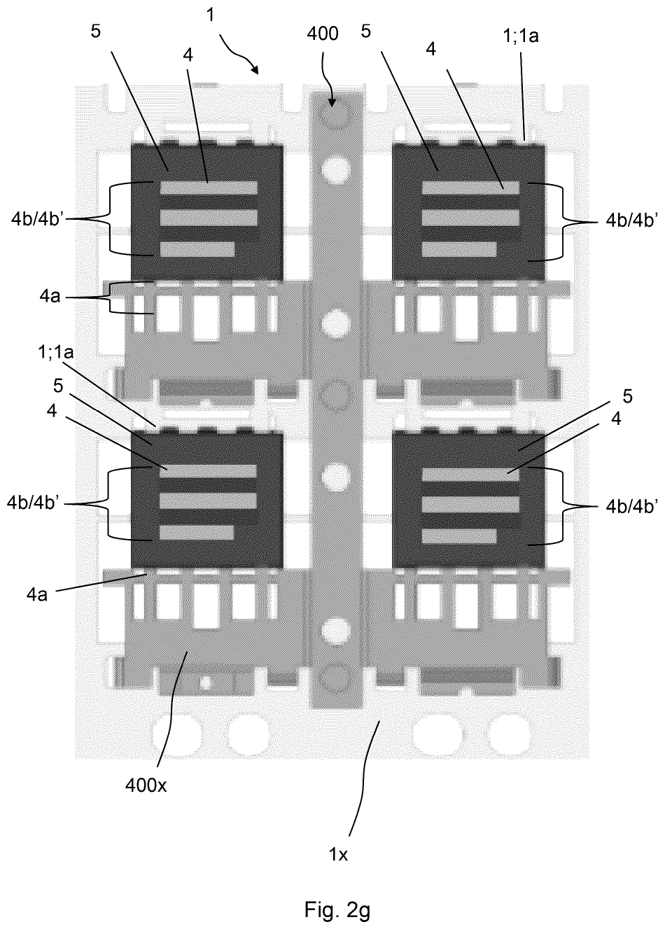

FIGS. 1a-1d, combined with FIGS. 2a-2g, depict in a schematic way the sequence steps of manufacturing an example of a semiconductor device according to the disclosure. These sequence steps of the method according to the disclosure present a solution for the ongoing concern on heat dissipation in power packages, such as MOSFET devices. Mitigating this concern it is major a goal of the present disclosure to provide a novel power package with an improved heat dissipation.

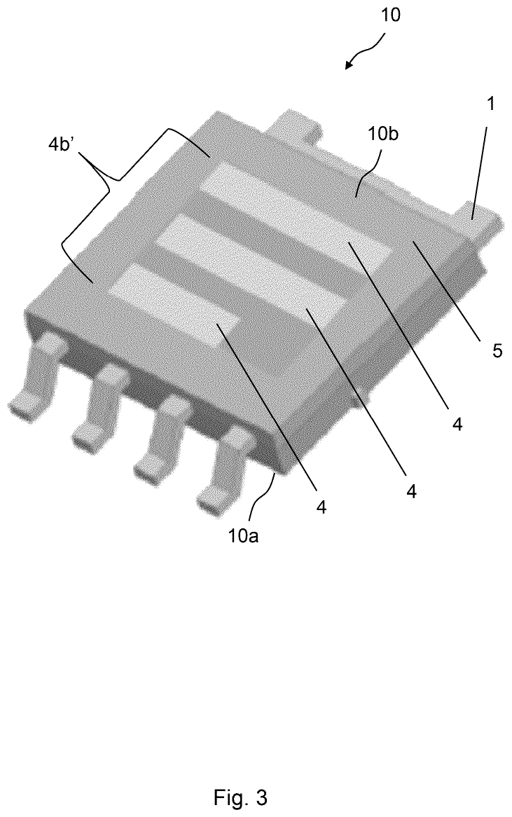

As shown in the various partial views of FIGS. 1a-1d, also combined with FIG. 3, an example of a semiconductor device according to the disclosure is presented. The final package is depicted in FIG. 1d and 3, and the semiconductor device is denoted with reference numeral 10. It comprises a lead frame 1 with a first lead frame surface 1a and a second lead frame surface 1b, opposite the first lead frame surface 1a, as well as a semiconductor die 3 comprising a first semiconductor die surface 3a and a second semiconductor die surface 3b, opposite the first semiconductor die surface 3a (FIG. 1b). In addition, a clip 4 is implemented, which is composed of a flat part 4a and a corrugated part 4b.

The corrugated part 4b comprises at least one peak 4b′ and at least one valley 4b″. As shown in the example of e.g. FIG. 1a, the corrugated part 4b of the clip 4 comprises at least two peaks 4b′, more in particular three peaks 4b′. However more than two peaks 4b′ can be used, for example four peaks 4b′. The number of peaks 4b′ contribute to an enlargement of the heat dissipating surface of the clip 4.

The second lead frame surface 1b of the lead frame 1 is connected to the first semiconductor die surface 3a of the semiconductor die 3, and the second semiconductor die surface 3b of the semiconductor die 3 is connected to the corrugated part 4b of the clip 4, using a connection technique which will be outlined further in the detailed description.

The complete assembly formed by the semiconductor die 3, the at least one valley 4b″ of the corrugated part 4b of the clip 4, and the lead frame 1 are encapsulated by means of a mold compound 5. The encapsulated end product or package 10 is shown in FIG. 1d, and shows that after encapsulation the mold compound 5 forms an outer surface of the semiconductor device 10 with at least one peak 4b′ of the corrugated part 4b of the clip 4, at least part of the flat part 4a of the clip 4, and the first lead frame surface 1a of the lead frame 1 being exposed.

These exposed elements of the package 10 effectively function as an enlarged heat dissipation surface, in particular at an upper or top face 10b of the semiconductor device 10. Also the exposed first lead frame surface 1a of the lead frame 1 forms the (first) lower surface 10a of the semiconductor device 10 and effectively functions as a drain terminal tab (also denoted with 1a). Usually, heat generated during operating the semiconductor device 10 is dissipated from an area with a high (hot) temperature towards an area with a lower (colder) temperature. Thus, the presence of additional heat sink functionality formed by the exposed corrugated part 4b′ and flat part 4a of the clip 4 provides an additional heat dissipation at the upper surface 10b of the semiconductor device 10 aside from the commonly used heat sink formed by the drain terminal tab 1a. Accordingly, this configuration results in an improved electrical efficiency of the semiconductor device 10, e.g. formed as a MOSFET or transistor.

The second lead frame surface 1b of the lead frame 1 is connected to the first semiconductor die surface 3a of the semiconductor die 3, and/or the second semiconductor die surface 3b of the semiconductor die 3 is connected to the corrugated part 4b of the clip 4 by means of soldering, sintering, or ultrasonic bonding. Soldering is the recommended process according to the example, as this allows for applying a required uniform solder volume, which prevents solder voids and/or insufficient soldering material. The connection between the lead frame 1 and the semiconductor die 3, and between the semiconductor die 3 and the clip 4 is schematically shown by means of reference numeral 2 (denoting for example solder paste) in FIG. 1b and also in FIGS. 2b and 2d.

As shown in more detail in FIGS. 1d and 3, the mold compound 5 and the at least one peak 4b′ of the corrugated part 4b of the clip 4 form a single planar (upper) surface 10b of the semiconductor device 10, thus constituting an optimal heat sink surface with improved heat dissipation.

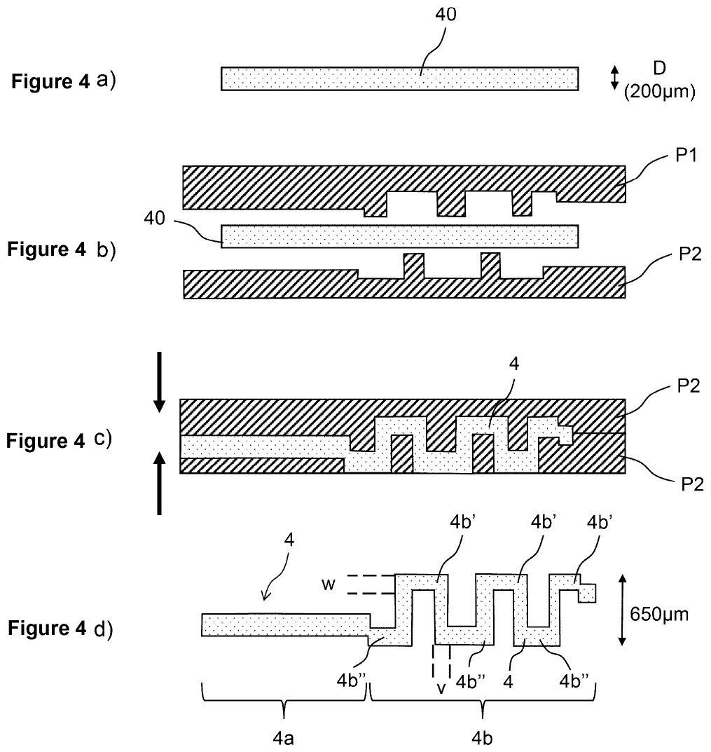

It is preferred that the lead frame 1 and/or the clip 4 are made of a conductive metal sheet, for example copper or aluminum. In particular, in the example of the clip 4 being made of a conductive metal sheet, the sheet has preferably a width of 200 μm, see FIG. 4a. Preferably, a width or thickness w of the corrugated part 4b is two times the width/thickness v of the metal sheet in between peaks 4b′, see FIG. 4d.

FIGS. 2a-2g combined with FIGS. 1a-1d and FIGS. 4a-4d, show the various steps of an example of a method of manufacturing a semiconductor device according to the disclosure.

The method may comprise the steps of forming a clip 4 which comprises a flat part 4a and a corrugated part 4b, wherein the corrugated part comprises at least one peak 4b′ and at least one valley 4b″. The forming of such clip 4 is depicted in FIGS. 4a-4b and starts with a starting strip material 40 (FIG. 4a) having a certain thickness D, which may be 200 μm. The starting strip material 40 is placed between two preform plates or press dies P1 and P2, which are provided with a preform shape, see FIG. 4b. Both press dies P1 and P2 are moved towards each (FIG. 4c) and form or punch the starting strip material 40 into the resulting clip 4 (FIG. 4d) composed of a flat part 4a and a corrugated part 4b, wherein the corrugated part comprises at least one peak 4b′ and at least one valley 4b″. As stipulate above, a width or thickness w of the corrugated part 4b is two times the width/thickness v of the metal sheet in between peaks 4b′.

Alternatively, and as shown in FIGS. 2e-2g, each corrugated clip 4 is accommodated in a so-called clip matrix 400, which contains a plurality of corrugated clips 4.

With the preformed clip 4 thus obtained, the method of manufacturing the semiconductor device 10 continues with the step ii) of connecting a semiconductor die 3 to a lead frame 1. The lead frame 1 is shown in FIG. 2a and in particular is depicted as a lead frame matrix (also denoted with reference numeral 1) suited for manufacturing a plurality of semiconductor devices in one sequence. The lead frame 1 is provided with several die attach paddles 1z which function as mounting surface of a semiconductor die 3.

As shown in the Figures, the lead frame 1 comprises a first lead frame surface 1a and a second lead frame surface 1b opposite the first lead frame surface 1a. Likewise, the semiconductor die 3 comprises a first semiconductor die surface 3a and a second semiconductor die surface 3b opposite first semiconductor die surface 3a. When mounting or connecting the semiconductor die 3, see FIG. 2c, on a corresponding die attach paddle 1z, the second lead frame surface 1b of the lead frame 1 is connected to the first semiconductor die surface 3a of the semiconductor die 3.

In a next step iii), shown in FIG. 2e, the clip 4 is connected to the semiconductor device 3 such that the second semiconductor die surface 3b of the semiconductor die 3 is connected to the corrugated part 4b of the clip 4. Step iii) can be facilitated by mounting the clip matrix 400 containing a plurality of corrugated clips 4 on to the lead frame matrix 1, such that the matrix of individual clips 4 exactly overlap with the plurality of semiconductor dies 3, each mounted to a die attach paddle 1z.

The connecting steps ii) and iii) can be achieved by a multitude of connection techniques, such as soldering, sintering, or ultrasonic bonding between the second lead frame surface 1b of the lead frame 1 and the first semiconductor die surface 3a of the semiconductor die 3 and/or between the second semiconductor die surface 3b of the semiconductor die 3 and the corrugated part 4b of the clip 4.

In the FIGS. 2b and 2d, these connections are schematically depicted by means of reference numeral 2, which might include a solder paste and solder material. Preferably, a soldering connection is performed, as soldering is the recommended process according to the example, as this allows for applying a required uniform solder volume, which prevents solder voids and/or insufficient soldering material.

FIG. 2f depicts the next method step iv) of encapsulating each assembly formed by the semiconductor die 3, the at least one valley 4b″ of the corrugated part 4b of the clip 4, and the lead frame 1 with a mold compound 5. The resulting encapsulant packages are shown in FIG. 2f wherein at least one peak 4b′ of the corrugated part 4b of the clip 4, at least part of the flat part 4a of the clip 4, and the first lead frame surface 1a of the lead frame 1 are exposed. See also FIGS. 1d and 3.

Usually, the encapsulating step iv) results in the at least one peak 4b′ of the corrugated part 4b of the clip 4 also being covered by the mold compound 5. This is depicted in FIG. 1c and also in FIG. 2f, wherein the corrugated parts 4b of each clip 4 are covered by mold compound 5, the covering being illustrated by depicting the peaks 4b′ by means of dashed lines and with a shading which is slightly lighter than the shading of the mold compound 5.

Accordingly, with the peaks 4b′ being encapsulated by the mold compound 5, no heat dissipation can be achieved. Thus, the encapsulating step iv) may be followed by a polishing step vi), see FIGS. 2g and 1d, such that the at least one peak 4b′ of the corrugated part 4b of the clip 4 becomes exposed and the mold compound 5 and the at least one peak 4b′ of the corrugated part 4b of the clip 4 forms a single plane surface. This results in a semiconductor device with an effective, flat heat sink upper surface 10b with an improved heat dissipation.

In a final step, the semiconductor device is singulated from the lead frame matrix 1 and the clip matrix 400, through removal with known techniques of the excessive lead frame parts 1x and clip matrix parts 400x (see FIG. 2g). This results in a singulated semiconductor device 10 (FIG. 3) wherein the exposed corrugated part 4b′ and flat part 4a of the clip effectively function as an enlarged heat dissipation surface, in particular at an upper or top face 10b of the semiconductor device 10.

### LIST OF REFERENCE NUMERALS USED

1 lead frame/lead frame matrix
1a first lead frame surface
1b second lead frame surface
1x excessive lead frame parts
1z die attach paddle
2 solder paste/solder material
3 semiconductor die
3a first semiconductor die surface
3b second semiconductor die surface
4 clip
4a flat part
4b corrugated part
4b′ peak
4b″ valley
40 starting strip material for clip 4
400 clip matrix
400x excessive clip matrix parts
5 mould compound
10 semiconductor device singulated
10a first, lower surface of semiconductor device
10b second, top or upper surface of semiconductor device
P1-P2 press plates or press dies

What is claimed is:

1. A semiconductor device comprising:
a lead frame comprising a first lead frame surface and a second lead frame surface opposite the first lead frame surface;
a semiconductor die comprising a first semiconductor die surface and a second semiconductor die surface opposite the first semiconductor die surface;
a clip comprising a flat part and a corrugated part, wherein the corrugated part comprises at least two peaks and at least one valley;
a mold compound;
wherein the second lead frame surface of the lead frame is connected to the first semiconductor die surface of the semiconductor die, and wherein the second semiconductor die surface of the semiconductor die is connected to the corrugated part of the clip, and
wherein the mold compound encapsulates the semiconductor die, and the at least one valley of the corrugated part of the clip so that the mold compound forms an outer surface of the semiconductor device with the at least two peaks of the corrugated part of the clip, at least part of the flat part of the clip, and the first lead frame surface of the lead frame are exposed.

2. The semiconductor device according to claim 1, wherein the second lead frame surface of the lead frame is connected to the first semiconductor die surface of the semiconductor die, and/or the second semiconductor die surface of the semiconductor die is connected to the corrugated part of the clip by a method selected from the group consisting of soldering, sintering, and ultrasonic bonding.

3. The semiconductor device according to claim 1, wherein the mold compound and the at least one peak of the corrugated part of the clip forms a single planar surface.

4. The semiconductor device according to claim 1, wherein the lead frame and/or the clip are made of a conductive metal sheet.

5. The semiconductor device according to claim 1, wherein the clip is made of a metal sheet and has a width of 200 μm, and wherein the corrugated part has a width that is two times the width of the metal sheet.

6. The semiconductor device according to claim 1, wherein the corrugated part of the clip comprises three or four peaks.

7. The semiconductor device according to claim 2, wherein the mold compound and the at least one peak of the corrugated part of the clip forms a single planar surface.

8. The semiconductor device according to claim 2, wherein the lead frame and/or the clip are made of a conductive metal sheet.

9. The semiconductor device according to claim 2, wherein the clip is made of a metal sheet and has a width of 200 μm, and wherein the corrugated part has a width that is two times width of the metal sheet.

10. The semiconductor device according to claim 2, wherein the corrugated part of the clip comprises three or four peaks.

11. A method of manufacturing a semiconductor device according to claim 1, comprising steps of:
i) forming a clip which comprises a flat part and a corrugated part, wherein the corrugated part comprises at least two peaks and at least one valley;
ii) connecting a semiconductor die, which comprises a first semiconductor die surface and a second semiconductor die surface opposite first semiconductor die surface, to a lead frame that comprises a first lead frame surface and a second lead frame surface opposite the first lead frame surface, so that the second lead frame surface of the lead frame is connected to the first semiconductor die surface of the semiconductor die;
iii) connecting the clip to the semiconductor device so that the second semiconductor die surface of the semiconductor die is connected to the corrugated part of the clip; and
iv) encapsulating with a mold compound so that the at least two peaks of the corrugated part of the clip, at least part of the flat part of the clip, and the first lead frame surface of the lead frame are exposed.

12. The method according to claim 11, wherein the connecting steps ii) and iii) further comprise the sub-step of:
v) applying a connection by a method selected from the group consisting of soldering, sintering, and ultrasonic bonding between the second lead frame surface of the lead frame and the first semiconductor die surface of the semiconductor die and/or between the second semiconductor die surface of the semiconductor die and the corrugated part of the clip.

13. The method according to claim 11, wherein the encapsulating step iv) is followed by the step of:
vi) polishing, so that the mold compound and the at least one peak of the corrugated part of the clip forms a single plane surface.

14. The method according to claim 11, wherein the clip is made by punching a metal sheet.

15. The method according to claim 11, wherein the clip is made by forming a metal sheet.

16. The method according to claim 11, further comprising a finalizing step of singulating the semiconductor device.

17. The method according to claim 12, wherein the encapsulating step iv) is followed by the step of:
vi) polishing, so that the mold compound and the at least one peak of the corrugated part of the clip forms a single plane surface.

18. The method according to claim 12, wherein the clip is made by punching a metal sheet.

19. The method according to claim 12, wherein the clip is made by forming a metal sheet.

20. The method according to claim 12, further comprising a finalizing step of singulating the semiconductor device.
